(19) United States
(12) Patent Application Publication
(10) Pub. No.: US 2026/0303029 A1
(43) Pub. Date: Oct. 1, 2026

(54) TRANSMISSION CIRCUIT AND COMMUNICATION DEVICE EQUIPPED WITH THE SAME

(71) Applicant: Murata Manufacturing Co., Ltd., Nagaokakyo-shi (JP)

(72) Inventor: Kenji TAHARA, Nagaokakyo-shi (JP)

(21) Appl. No.: 19/578,159

(22) Filed: Mar. 25, 2026

(30) Foreign Application Priority Data
Mar. 28, 2025 (JP) 2025-055657

(51) Int. Cl. H03F 1/02; H03F 3/24; H04B 1/04

(52) U.S. Cl. CPC H03F 1/0288; H03F 3/245; H04B 1/04; H03F 2200/451

(57) ABSTRACT

A transmission circuit is a transmission circuit that amplifies and transmits a high-frequency signal to antennas corresponding to frequency bands different from each other. The transmission circuit includes an input terminal, output terminals, amplifier circuits, an output circuit, and phase-shifting lines. Each amplifier circuit amplifies the high-frequency signal received by the input terminal. The output circuit is connected to the two amplifier circuits and the two output terminals. Each phase-shifting line has an electric length of one-eighth wavelength. Each amplifier circuit includes a carrier amplifier, a peak amplifier, a hybrid coupler, and a switch. The output circuit includes a hybrid coupler and switches. The phase-shifting lines are connected to the input ends of the carrier amplifier and the peak amplifier of the amplifier circuit and the output end of the amplifier circuit.

### CROSS REFERENCE TO RELATED APPLICATION

This application claims priority from Japanese Patent Application No. 2025-055657, filed on Mar. 28, 2025. The content of this application is incorporated herein by reference in its entirety.

### BACKGROUND OF THE DISCLOSURE

### 1. Field of the Disclosure

The present disclosure relates to a transmission circuit and a communication device equipped with the same and more particularly to a technique for improving the robustness of the transmission circuit having amplifiers against load fluctuations.

### 2. Description of the Related Art

Japanese Unexamined Patent Application Publication No. 2013-85179 (Patent Document 1) discloses a power amplifier circuit including an amplifier output phase shifter connected between the output terminal of a carrier amplifier (a first amplifier) and the output terminal of a peak amplifier (a second amplifier) and a transformer connected to the amplifier output phase shifter and the output terminal of the peak amplifier.

The power amplifier circuit disclosed in Patent Document 1 is what is called a Doherty amplifier circuit. In the power amplifier circuit disclosed in Patent Document 1, fluctuations in the impedance of a load connected to the output terminal of the power amplifier circuit change impedance in the two amplifiers, causing output power from each amplifier to fluctuate and become unstable.

### BRIEF SUMMARY OF THE DISCLOSURE

The present disclosure has been made to solve such a problem and aims to improve the robustness of a transmission circuit having two amplifier circuits against load fluctuations.

A transmission circuit according to the present disclosure is a transmission circuit that amplifies and transmits a high-frequency signal to a first antenna and a second antenna respectively corresponding to a first frequency band and a second frequency band different from each other. The transmission circuit includes an input terminal that receives a high-frequency signal, a first output terminal, a second output terminal, a first amplifier circuit, a second amplifier circuit, an output circuit, and first to third phase-shifting lines. The first output terminal and the second output terminal are connected to the first antenna and the second antenna, respectively. The first amplifier circuit and the second amplifier circuit amplify the high-frequency signal received by the input terminal. The output circuit is connected to the first amplifier circuit, the second amplifier circuit, the first output terminal, and the second output terminal. The first to third phase-shifting lines each have an electric length of one-eighth wavelength. The first amplifier circuit includes a first carrier amplifier, a first peak amplifier, a first hybrid coupler, and a first switch. The second amplifier circuit includes a second carrier amplifier, a second peak amplifier, a second hybrid coupler, and a second switch. The output circuit includes a third hybrid coupler, a third switch, and a fourth switch. The first hybrid coupler, the second hybrid coupler, and the third hybrid coupler each include a first input node, a second input node, a first output node, and a second output node. The first phase-shifting line is connected to an input end of the second carrier amplifier. The second phase-shifting line is connected to an input end of the second peak amplifier. The first input node of the first hybrid coupler is connected to an output end of the first carrier amplifier. The second input node of the first hybrid coupler is connected to an output end of the first peak amplifier. The first output node of the first hybrid coupler is connected to a ground potential through the first switch. The first input node of the second hybrid coupler is connected to an output end of the second carrier amplifier. The second input node of the second hybrid coupler is connected to an output end of the second peak amplifier. The first output node of the second hybrid coupler is connected to the ground potential through the second switch. The first input node of the third hybrid coupler is connected to the second output node of the first hybrid coupler. The second input node of the third hybrid coupler is connected to the second output node of the second hybrid coupler through the third phase-shifting line. The first output node of the third hybrid coupler is connected to the first output terminal and is also connected to the ground potential through the third switch. The second output node of the third hybrid coupler is connected to the second output terminal and is also connected to the ground potential through the third switch.

In the transmission circuit according to the present disclosure, the two amplifier circuits (the first amplifier circuit and the second amplifier circuit) are connected to the antennas (the first antenna and the second antenna) through the output circuit having a hybrid coupler (the third hybrid coupler), and phase-shifting lines (the first to third phase-shifting lines) having an electric length of one-eighth wavelength are provided at the input side and the output side of the second amplifier circuit. With this configuration, when signals from the two amplifier circuits are synthesized in the output circuit and outputted to the antennas, the load phase of the output power from the second amplifier circuit can be shifted by 90° relative to the phase of the output power from the first amplifier circuit. As a result, fluctuations in output power due to antenna load fluctuations can be suppressed over the entire range of load phase. Further, the configuration enables output power from either one of the amplifier circuits to be higher than average power at any load phase. This enables improvement in the robustness of a transmission circuit having two amplifier circuits against load fluctuations.

### BRIEF DESCRIPTION OF THE SEVERAL VIEWS OF THE DRAWINGS

FIG. 1 is a schematic configuration diagram of a communication device to which a transmission circuit according to an embodiment is applied;

FIG. 2 is a diagram showing a detailed configuration of a power amplifier circuit in FIG. 1;

FIG. 3 is a diagram illustrating a circuit state in a case of outputting a high-frequency signal from one of antennas in a first mode (series-series synthesis mode);

FIG. 4 is a diagram illustrating a circuit state in a case of outputting a high-frequency signal from the other antenna in the first mode;

FIG. 5 is a diagram illustrating a power amplifier circuit of a comparative example;

FIG. 6 is a diagram illustrating the characteristics of the power amplifier circuit of the embodiment;

FIG. 7 is a diagram illustrating outputs from the amplifiers in a case of maximum power in the first mode;

FIG. 8 is a diagram illustrating outputs from the amplifiers in a case of 6-dB backoff in the first mode;

FIG. 9 is a diagram illustrating outputs from the amplifiers in a case of 12-dB backoff in the first mode;

FIG. 10 is a diagram illustrating a circuit state in a case of outputting a high-frequency signal from one of the antennas in a second mode (series-parallel synthesis mode);

FIG. 11 is a diagram illustrating a circuit state in a case of outputting a high-frequency signal from the other antenna in the second mode;

FIG. 12 is a diagram illustrating outputs from the amplifiers in a case of maximum power in the second mode;

FIG. 13 is a diagram illustrating outputs from the amplifiers in a case of 6-dB backoff in the second mode;

FIG. 14 is a diagram illustrating a circuit state in a case of outputting a high-frequency signal from one of the antennas in a third mode (parallel-parallel synthesis mode);

FIG. 15 is a diagram illustrating a circuit state in a case of outputting a high-frequency signal from the other antenna in the third mode; and

FIG. 16 is a diagram illustrating outputs from the amplifiers in the third mode.

### DETAILED DESCRIPTION OF THE DISCLOSURE

An embodiment of the present disclosure is described in detail below with reference to the drawings. Note that the same or corresponding portions are denoted by the same reference numeral in the drawings and are not described repetitively.

### (Overall Configuration of Communication Device)

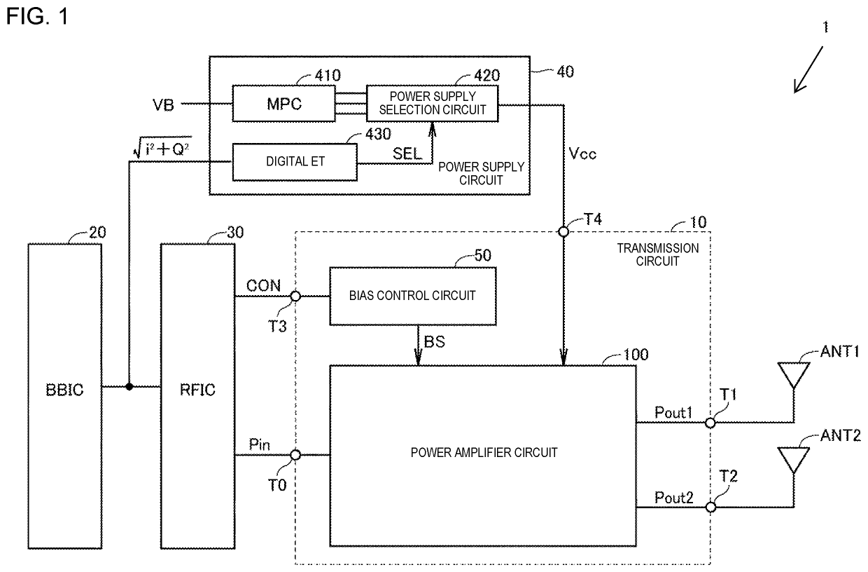

FIG. 1 is a schematic configuration diagram of a communication device 1 to which a transmission circuit 10 according to the embodiment is applied. The communication device 1 is, for example, a mobile terminal such as a mobile phone, a smartphone, or a tablet, a personal computer with communication capability, or a base station for mobile terminals.

Referring to FIG. 1, the communication device 1 includes antennas ANT1 and ANT2, the transmission circuit 10, a baseband integrated circuit (BBIC) 20 forming a baseband signal processing circuit, a radio frequency integrated circuit (RFIC) 30, and a power supply circuit 40. The transmission circuit 10 includes input terminals T0, T3, and T4, output terminals T1 and T2, a bias control circuit 50, and a power amplifier circuit 100. In broad outline, the communication device 1 up-converts, in the RFIC 30, an intermediate-frequency (IF) signal conveyed from the BBIC 20 into a high-frequency (radio-frequency (RF)) signal, amplifies the high-frequency signal in the power amplifier circuit 100, and radiates the signal from the antennas ANT1 and ANT2.

The RFIC 30 is an example of a signal processing circuit that processes a high-frequency signal. The RFIC 30 up-converts an intermediate-frequency signal conveyed from the BBIC 20 into a high-frequency signal and outputs the generated high-frequency signal to the transmission circuit 10 through the input terminal T0.

The power supply circuit 40 is an example of what is called a digital tracker and can supply the power amplifier circuit 100 with a power supply voltage Vcc in a plurality of different voltage levels. The power supply circuit 40 includes a multilevel power converter (MPC) 410, a power supply selection circuit 420, and a digital envelope tracker (digital ET) 430.

The MPC 410 includes a plurality of DC/DC converters, although they are not shown in FIG. 1. The MPC 410 converts a battery voltage VB supplied from an external battery into a plurality of different voltage levels and supplies them to the power supply selection circuit 420.

The digital ET 430 receives I, Q waveform signals of a transmission signal from the BBIC 20 and performs envelope tracking of the transmission signal in digital ET mode. The digital ET 430 generates a selection signal SEL corresponding to the voltage level of the envelope of the transmission signal and outputs the selection signal SEL to the power supply selection circuit 420.

The power supply selection circuit 420 selects a voltage that corresponds to the selection signal SEL from the plurality of voltage levels supplied from the MPC 410 and supplies the voltage as the power supply voltage Vcc to the power amplifier circuit 100 through the input terminal T4.

The bias control circuit 50 receives a control signal CON received from the RFIC 30 through the input terminal T3. The bias control circuit 50 generates a bias signal BS based on the control signal CON and outputs the bias signal BS to the power amplifier circuit 100, the bias signal BS being for controlling the magnitude of the bias current and the timing of its supply for amplifiers included in the power amplifier circuit 100.

The power amplifier circuit 100 generates output signals Pout1 and Pout2 by amplifying an input signal Pin received from the RFIC 30 through the input terminal T0. The output signals Pout1 and Pout2 generated are respectively conveyed to the corresponding antennas ANT1 and ANT2 through the output terminals T1 and T2 and are radiated as radio waves.

The antennas ANT1 and ANT2 are, for example, planar patch antennas with a square shape. Note that the shape of the antennas ANT1 and ANT2 is not limited to a square and may be circular or any other polygonal shape. Also, the antennas ANT1 and ANT2 may be antennas other than patch antennas.

The antennas ANT1 and ANT2 are configured to radiate radio waves in frequency bands different from each other. For example, the antenna ANT1 has a size capable of radiating radio waves in a first frequency band (Band-A), and the antenna ANT2 has a size capable of radiating radio waves in a second frequency band (Band-B). (Detailed Configuration of Power Amplifier Circuit)

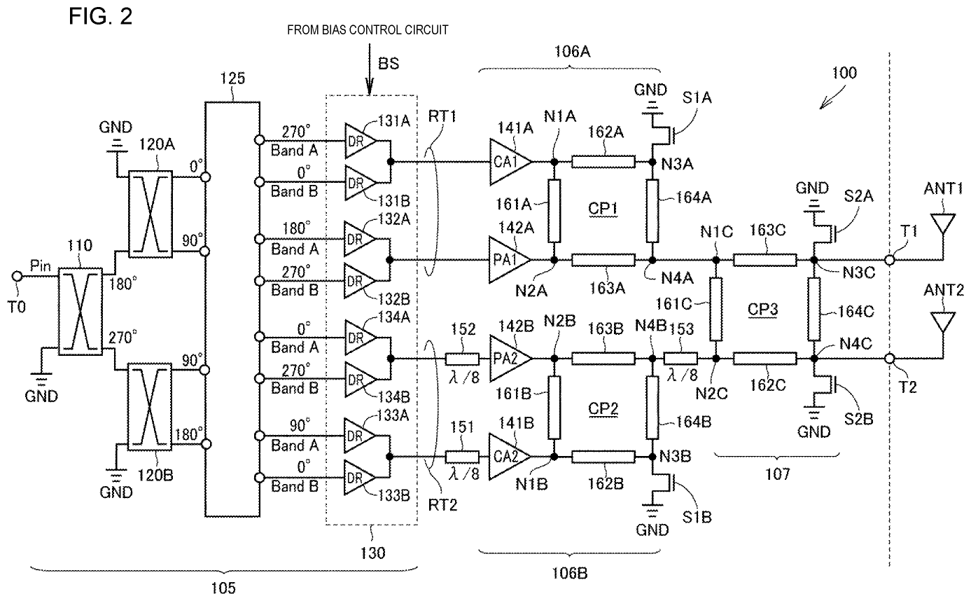

Next, a detailed configuration of the power amplifier circuit 100 is described using FIG. 2. The power amplifier circuit 100 includes a phase adjuster circuit 105, and amplifier circuits 106A and 106B, an output circuit 107, and phase-shifting lines 151, 152, and 153.

The phase adjuster circuit 105 branches the input signal Pin into a plurality of routes, adjusts the phases of the branched signals, and conveys them to the amplifier circuits 106A and 106B. The phase adjuster circuit 105 includes hybrid couplers 110, 120A, and 120B, a branching circuit 125, and a drive amplifier 130. Each of the hybrid couplers 110, 120A, and 120B includes two input nodes and two output nodes. Each hybrid coupler has one of its input nodes grounded, branches a high-frequency signal received by the other input node into two routes, and gives the two branched signals a 90°-phase difference.

The other input node of the hybrid coupler 110 is connected to the input terminal T0. The hybrid coupler 110 is connected at one output node to the other input node of the hybrid coupler 120A and at the other output node to the other input node of the hybrid coupler 120B.

The output nodes of the hybrid couplers 120A and 120B are connected to the branching circuit 125. In the branching circuit 125, four input signals are adjusted in phase and branched further into eight routes. The eight branched signals are supplied to eight corresponding amplifiers 131A to 134A and 131B to 134B included in the drive amplifier 130.

The drive amplifier 130 is a drive amplifier for supplying signals to amplifiers included in the amplifier circuits 106A and 106B. Based on the bias signal BS from the bias control circuit 50, the drive amplifier 130 switches the amplifiers used for supplying signals to the amplifier circuits 106A and 106B.

With the phase of the signal supplied to the amplifier 131B being a reference (0°), signals with the same phase (0°) are supplied to the amplifier 133B and the amplifier 134A as well, and a signal with a 90° phase advance is supplied to the amplifier 133A. A signal with a 180° phase advance, i.e., a signal having an opposite phase, is supplied to the amplifier 132A. A signal with a 270° phase advance, or a 90° phase delay, is supplied to the amplifiers 131A, 132B, and 134B.

Note that in the following description, a route taken by a signal passing through the amplifier circuit 106A is referred to as a route RT1, and a route taken by a signal passing through the amplifier circuit 106B is referred to as a route RT2.

The amplifier circuit 106A includes a carrier amplifier 141A, a peak amplifier 142A, a hybrid coupler CP1, and a switch S1A. The hybrid coupler CP1 is formed by four phase-shifting lines 161A to 164A connected annularly. The phase-shifting lines 161A to 164A each have an electric length of one-quarter wavelength at the center frequency of the transmission-target frequency band.

A connection node N1A between the phase-shifting line 161A and the phase-shifting line 162A corresponds to one of input nodes of the hybrid coupler CP1 and is connected to the output end of the carrier amplifier 141A. A connection node N2A between the phase-shifting line 161A and the phase-shifting line 163A corresponds to the other input node of the hybrid coupler CP1 and is connected to the output end of the peak amplifier 142A.

A connection node N3A between the phase-shifting line 162A and the phase-shifting line 164A corresponds to one of output nodes of the hybrid coupler CP1 and is connected to a ground potential GND through the switch S1A. A connection node N4A between the phase-shifting line 163A and the phase-shifting line 164A corresponds to the other output node of the hybrid coupler CP1 and is connected to the output circuit 170.

The amplifiers 131A and 131B in the drive amplifier 130 are connected to the input end of the carrier amplifier 141A. Also, the amplifiers 132A and 132B in the drive amplifier 130 are connected to the input end of the peak amplifier 142A. To radiate radio waves in Band-A from the antenna ANT1, high-frequency signals are supplied from the amplifier 131A and the amplifier 132A to the carrier amplifier 141A and the peak amplifier 142A, respectively. To radiate radio waves in Band-B from the antenna ANT2, high-frequency signals are supplied from the amplifier 131B and the amplifier 132B to the carrier amplifier 141A and the peak amplifier 142A, respectively.

The amplifier circuit 106B includes a carrier amplifier 141B, a peak amplifier 142B, a hybrid coupler CP2, and a switch S1B. The hybrid coupler CP2 is formed by four phase-shifting lines 161B to 164B connected annularly. The phase-shifting lines 161B to 164B each have an electric length of one-quarter wavelength at the center frequency of the transmission-target frequency band.

A connection node N1B between the phase-shifting line 161B and the phase-shifting line 162B corresponds to one of input nodes of the hybrid coupler CP2 and is connected to the output end of the carrier amplifier 141B. A connection node N2B between the phase-shifting line 161B and the phase-shifting line 163B corresponds to the other input node of the hybrid coupler CP2 and is connected to the output end of the peak amplifier 142B.

A connection node N3B between the phase-shifting line 162B and the phase-shifting line 164B corresponds to one of output nodes of the hybrid coupler CP2 and is connected to the ground potential GND through the switch S1B. A connection node N4B between the phase-shifting line 163B and the phase-shifting line 164B corresponds to the other output node of the hybrid coupler CP2 and is connected to the output circuit 170 through the phase-shifting line 153.

The amplifiers 133A and 133B in the drive amplifier 130 are connected to the input end of the carrier amplifier 141B. Also, the amplifiers 134A and 134B in the drive amplifier 130 are connected to the input end of the peak amplifier 142B. To radiate radio waves in Band-A from the antenna ANT1, high-frequency signals are supplied from the amplifier 133A and the amplifier 134A to the carrier amplifier 141B and the peak amplifier 142B, respectively. To radiate radio waves in Band-B from the antenna ANT2, high-frequency signals are supplied from the amplifier 133B and the amplifier 134B to the carrier amplifier 141B and the peak amplifier 142B, respectively.

The output circuit 107 includes a hybrid coupler CP3 and switches S2A and S2B. The hybrid coupler CP3 is formed by four phase-shifting lines 161C to 164C connected annularly. The phase-shifting lines 161C to 164C each have an electric length of one-quarter wavelength at the center frequency of the transmission-target frequency band.

A connection node N1C between the phase-shifting line 161C and the phase-shifting line 162C corresponds to one of input nodes of the hybrid coupler CP3 and is connected to the connection node N4A of the hybrid coupler CP1. A connection node N2C between the phase-shifting line 161C and the phase-shifting line 163C corresponds to the other input node of the hybrid coupler CP3 and is connected to the connection node N4B of the hybrid coupler CP2 through the phase-shifting line 153.

A connection node N3C between the phase-shifting line 162C and the phase-shifting line 164C corresponds to one of output nodes of the hybrid coupler CP3 and is connected to the ground potential GND through the switch S2A and is connected to the antenna ANT1 through the output terminal T1. A connection node N4C between the phase-shifting line 163C and the phase-shifting line 164C corresponds to the other output node of the hybrid coupler CP3 and is connected to the ground potential GND through the switch S2B and is connected to the antenna ANT2 through the output terminal T2.

The output circuit 107 switches the switches S2A and S2B between a conducting state and a non-conducting state, thereby enabling switching of the antennas to be used for radiating radio waves. In other words, by using the switches S2A and S2B, the output circuit 107 can switch the frequency band of the radio waves to be radiated from the communication device 1.

Further, the transmission circuit 10 of the present embodiment can switch its operation mode among first to third modes by switching the switches S1A, S1B, S2A, and S2B between a conducting state and a non-conducting state. More specifically, the signal synthesis mode of the hybrid couplers CP1 to CP3 can be switched based on settings of the switches S1A, S1B, S2A, and S2B.

The phase-shifting lines 151, 152, and 153 are provided on the route RT2, which is a signal path through the amplifier circuit 106B, and have an electric length of one-eighth wavelength at the center frequency of the transmission-target frequency band. The phase-shifting lines 151, 152, and 153 are provided to shift the load phase of an output signal from the amplifier circuit 106B relative to that of an output signal from the amplifier circuit 106A to improve robustness against antenna load fluctuations.

Circuit states in the respective operation modes are described below.

### (First Mode)

In the first mode, the switches S1A and S1B in the amplifier circuits 106A and 106B are brought to a conducting state, and the connection nodes N3A and N3B are grounded. Also, in the first mode, one of the switches S2A and S2B in the output circuit 107 is brought to a conducting state and the other one is brought to a non-conducting state, so that the connection node N3C or the connection node N4C is grounded.

This method of synthesizing two input signals with one of the output nodes of a hybrid coupler grounded is hereinafter referred to as “series synthesis”. In the first mode, an output from the carrier amplifier and an output from the peak amplifier are series-synthesized in each of the amplifier circuits 106A and 106B, and also, an output from the amplifier circuit 106A and an output from the amplifier circuit 106B are series-synthesized in the hybrid coupler CP3. Thus, the first mode is also referred to as “series-series synthesis mode”.

### (Antenna Switching Operation)

In the first mode, one of the switches in the output circuit 107 is brought to a conducting state. Thus, in the first mode, the antenna for radiating radio waves can be switched.

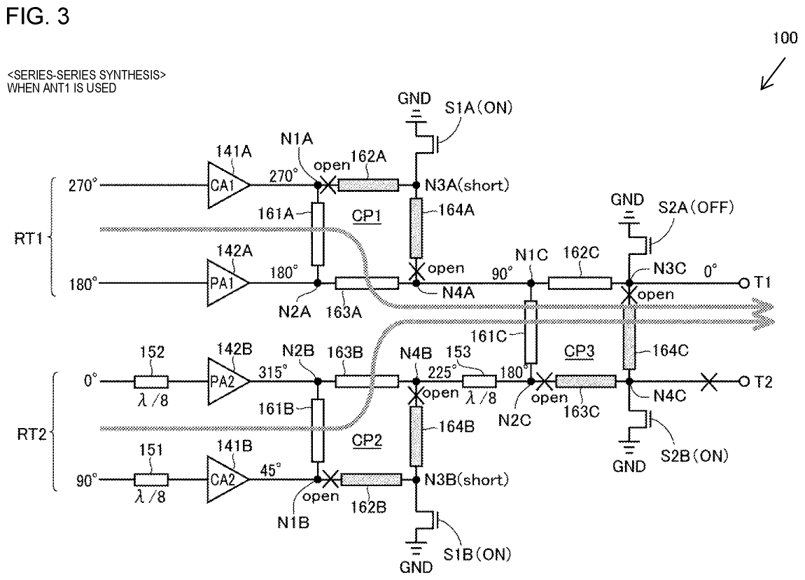

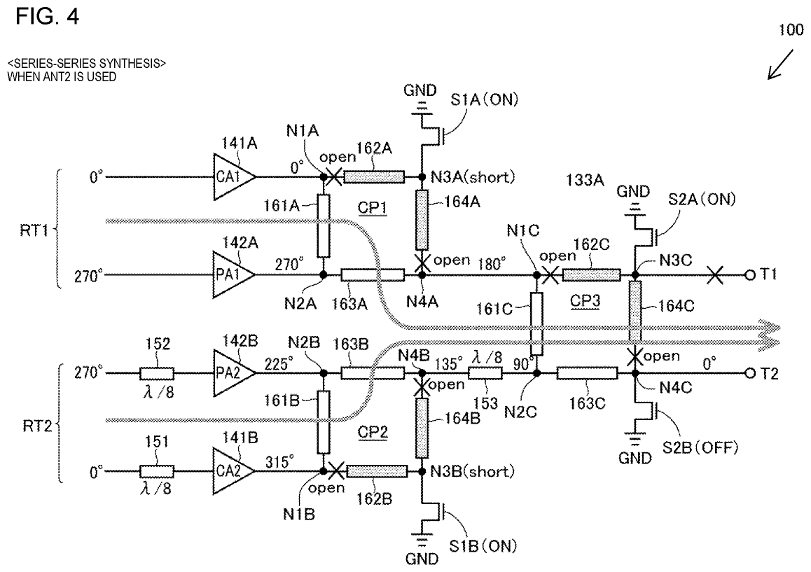

With reference to FIGS. 3 and 4, antenna switching operation in the first mode is described below. FIG. 3 is a diagram illustrating a circuit state in a case where a high-frequency signal is outputted from the antenna ANT1, and FIG. 4 is a diagram illustrating a circuit state in a case where a high-frequency signal is outputted from the antenna ANT2.

Referring to FIG. 3, in the amplifier circuit 106A, the impedance at the connection node N3A becomes a short circuit because the connection node N3A is grounded by the switch S1A as described above. In this event, with the phase-shifting lines 162A and 164A, the impedance when the phase-shifting line 162A is seen from the connection node N1A and the impedance when the phase-shifting line 164A is seen from the connection node N4A become an open circuit. Thus, an output signal from the carrier amplifier 141A takes a route passing through the phase-shifting lines 161A and 163A.

To radiate radio waves from the antenna ANT1, the drive amplifiers in the drive amplifier 130 are switched so as to supply a 270°-phase signal to the carrier amplifier 141A and a 180°-phase signal to the peak amplifier 142A. Thus, the carrier amplifier 141A is supplied with a signal with a 90° phase advance relative to that for the peak amplifier 142A.

In this way, a Doherty amplifier is formed by the carrier amplifier 141A, the peak amplifier 142A, and the phase-shifting line 161A. An output signal from the carrier amplifier 141A is delayed in phase by 90°by the phase-shifting line 161A and therefore becomes in phase with an output signal from the peak amplifier 142A at the connection node N2A, and the two signals are synthesized.

Similarly, in the amplifier circuit 106B, the impedance at the connection node N3B becomes a short circuit because the connection node N1B is grounded by the switch S1B. Thus, the impedance when the phase-shifting line 162B is seen from the connection node N1B and the impedance when the phase-shifting line 164B is seen from the connection node N4B both become an open circuit. For this reason, an output signal from the carrier amplifier 141B takes a route passing through the phase-shifting lines 161B and 163B.

Here, the drive amplifier 130 supplies a 90°-phase signal to the carrier amplifier 141B and supplies a 0°-phase signal to the peak amplifier 142B. More specifically, because the carrier amplifier 141B is supplied with a signal with a 90° phase advance relative to that for the peak amplifier 142B, a Doherty amplifier is formed by the carrier amplifier 141B, the peak amplifier 142B, and the phase-shifting line 161B.

Note that in the amplifier circuit 106B, the phase is delayed by 45° by the phase-shifting lines 151 and 152 provided at the input ends of the respective amplifiers and having an electric length of one-eighth wavelength, making an output signal from the carrier amplifier 141B have a 45° phase and an output signal from the peak amplifier 142B have a 315° (i.e., −45 °) phase.

An output signal from the carrier amplifier 141B is delayed in phase by 90° by the phase-shifting line 161B and therefore becomes in phase with an output signal from the peak amplifier 142B at the connection node N2B, and the two signals are synthesized.

The 180°-phase signal synthesized at the connection node N2A in the amplifier circuit 106A is delayed in phase by 90° by the phase-shifting line 163A, so that a signal at the connection node N1C of the hybrid coupler CP3 has a 90° phase. Meanwhile, the 315°-phase signal synthesized at the connection node N2B of the amplifier circuit 106B is delayed in phase by 135° by the phase-shifting line 163B and the phase-shifting line 153, so that a signal at the connection node N2C in the hybrid coupler CP3 has a 180° phase. Thus, the output signal from the amplifier circuit 106B is a signal with a 90° phase advance relative to the phase of the output signal from the amplifier circuit 106A.

In the case in FIG. 3, in the hybrid coupler CP3, the connection node N4C is grounded by the switch S2B, and thus, with the phase-shifting lines 163C and 164C, the impedance when the phase-shifting line 163C is seen from the connection node N2C and the impedance when the phase-shifting line 164C is seen from the connection node N3C become an open circuit. Thus, the output signal from the amplifier circuit 106B takes a route passing through the phase-shifting lines 161C and 162C. Thus, a Doherty amplifier is formed by the amplifier circuits 106A and 106B and the phase-shifting line 161C.

The 180°-phase signal supplied from the amplifier circuit 106B to the connection node N2C is delayed by 90° by the phase-shifting line 161C and therefore becomes in phase with the output signal from the amplifier circuit 106A at the connection node N1C, and the two signals are synthesized and outputted to the antenna ANT1.

Next, with reference to FIG. 4, a description is given of a case where radio waves are radiated from the antenna ANT2. In this case, the drive amplifiers in the drive amplifier 130 are switched so as to supply a 0°-phase signal to the carrier amplifiers 141A and 141B and a 270°-phase (i.e., −90°) signal to the peak amplifiers 142A and 142B.

Because the signals are synthesized in the amplifier circuits 106A and 106B in a similar manner to FIG. 3, the connection node N1C of the hybrid coupler CP3 is supplied with a 180°-phase signal, and the connection node N2C is supplied with a 90°-phase signal.

In radiating radio waves from the antenna ANT2, the switch S2A is brought to a conducting state to ground the connection node N3C. Thus, with the phase-shifting lines 162C and 164C, the impedance when the phase-shifting line 162C is seen from the connection node N1C and the impedance when the phase-shifting line 164C is seen from the connection node N4C both become an open circuit.

Thus, the output signal from the amplifier circuit 106A takes a route passing through the phase-shifting lines 161C and 163C. In this event, the 180°-phase signal supplied from the amplifier circuit 106A to the connection node N1C is delayed in phase by 90° by the phase-shifting line 161C and therefore becomes in phase with the output signal from the amplifier circuit 106B, and the two signals are synthesized and outputted to the antenna ANT2.

In this way, in the first mode, the antenna for radiating radio waves can be switched by switching of the switches S2A and S2B. In other words, in the first mode, the antennas can be switched to transmit radio waves in frequency bands different from each other.

### (Robustness Against Load Fluctuations)

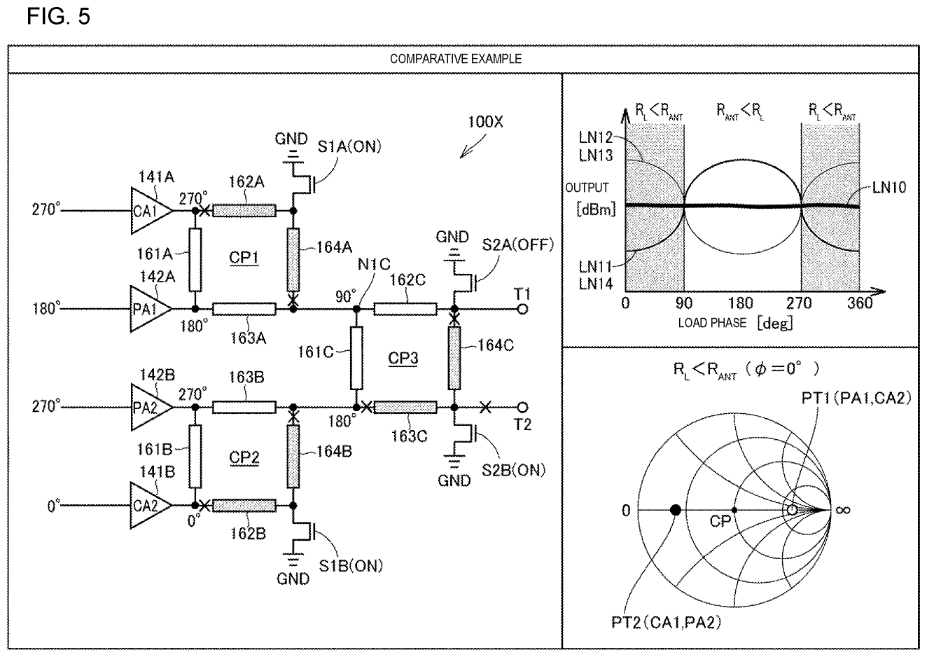

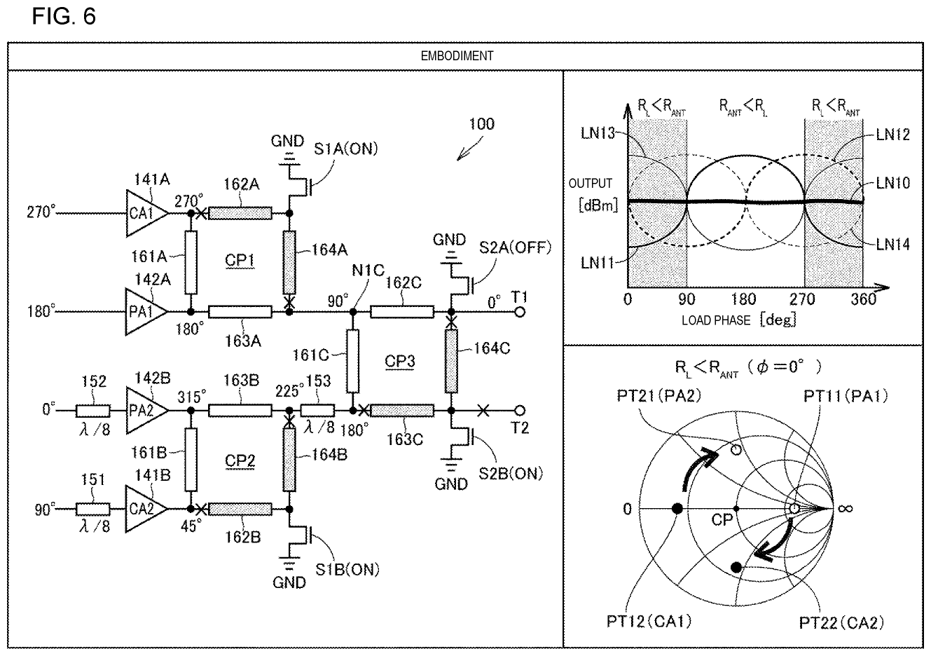

Next, robustness exhibited against antenna load fluctuations in the first mode is described using FIGS. 5 and 6.

As described above, in the power amplifier circuit 100 of the embodiment, the phase-shifting lines 151 to 153 are provided on the route RT2 to improve the robustness against antenna load fluctuations. The effects offered by the phase-shifting lines 151 to 153 are described using FIGS. 5 and 6. Note that FIGS. 5 and 6 show an example where all the amplifiers in the amplifier circuits are driven, and also, radio waves are radiated from the antenna ANT1.

FIG. 5 is a diagram showing a power amplifier circuit 100X of a comparative example where the phase-shifting lines 151 to 153 are not disposed. Also, FIG. 6 is a diagram showing the power amplifier circuit 100 of the present embodiment. The left field of each of FIGS. 5 and 6 shows a schematic configuration of the power amplifier circuit. The upper right field of each of FIGS. 5 and 6 shows a graph of fluctuations of output power from each amplifier caused by load fluctuations. The lower right field of each of FIGS. 5 and 6 shows the position of each amplifier on a Smith chart when the load phase φ=0° in a region where a load impedance R_{ANT} is greater than a characteristic impedance R_{L} (R_{L}<R_{ANT}).

First, referring to FIG. 5, in the power amplifier circuit 100X not provided with the phase-shifting lines 151 to 153, in a case where a 270°-phase signal is supplied to the carrier amplifier 141A and a 180°-phase signal is supplied to the peak amplifier 142A in the amplifier circuit 106A, a 0°-phase signal is supplied to the carrier amplifier 141B, and a 270°-phase signal is supplied to the peak amplifier 142B in the amplifier circuit 106B.

In the first mode, the amplifier circuits 106A and 106B operate as Doherty amplifiers. In a Doherty amplifier, the output end of the carrier amplifier is connected to the output end of the amplifier circuit (i.e., the output end of the peak amplifier) through a phase-shifting line having an electric length of one-quarter wavelength. Thus, the phase difference of the load phase between the load impedance of the carrier amplifier and the load impedance of the peak amplifier is 180°.

Thus, when, for example, the load impedance of the carrier amplifier is high, the load impedance of the peak amplifier is low. Conversely, when the load impedance of the carrier amplifier is low, the load impedance of the peak amplifier is high.

In the power amplifier circuit 100X of the comparative example, the amplifier circuit 106B is connected to the connection node N1C, which is a signal synthesis point, through the phase-shifting line 161C of the hybrid coupler CP3. Because the phase-shifting line 161C has an electric length of one-quarter wavelength, a 180° phase difference is further added to the load phase of the load impedance. As a result, the load phase of the load impedance of the carrier amplifier 141A and that of the peak amplifier 142B become in phase, and the load phase of the load impedance of the peak amplifier 142A and that of the carrier amplifier 141B become in phase.

A typical amplifier outputs lower power as the load impedance increases and outputs higher power as the load impedance decreases. Because a carrier amplifier and a peak amplifier in a Doherty amplifier behave reversely as described earlier, when the antenna's load impedance R_{ANT} becomes greater than the characteristic impedance R_{L} (R_{L}<R_{ANT}) due to load fluctuations, output power from the peak amplifier decreases, and output power from the carrier amplifier increases. Conversely, when the antenna's load impedance R_{ANT} becomes smaller than the characteristic impedance R_{L} (R_{L}>R_{ANT}), output power from the peak amplifier increases, and output power from the carrier amplifier decreases.

Thus, as shown in the graph in the upper right field of FIG. 5, load fluctuations of the carrier amplifier 141A (line LN11) and load fluctuations of the peak amplifier 142B (line LN14) exhibit similar graphs, and the load fluctuations of the peak amplifier 142A (line LN12) and load fluctuations of the carrier amplifier 141B (line LN13) exhibit similar graphs.

When this state is seen in the Smith chart in the lower right field, the peak amplifier 142A and the carrier amplifier 141B are located at a point PT1 rightward of a center CP, and the carrier amplifier 141A and the peak amplifier 142B are located at a point PT2 leftward of the center CP. The point PT1 is a position where the output power is the lowest, and the point PT2 is a position where the output power is the highest.

In this state, power fluctuations are cancelled out in each amplifier circuit by a change in the output power from the peak amplifier and a change in the output power from the carrier amplifier. As a result, average power output from the power amplifier circuit 100X exhibits a characteristic of being flat over the load phase and the entire range, as line LN10 shows.

However, if the phase changes from this state due to load fluctuations to a point where the magnitude relation between the antenna's load impedance R_{ANT} and the characteristic impedance R_{L} is switched (φ=90°, 270°), output power from both the peak amplifier and the carrier amplifier reaches the level of the average power. This means that, albeit a decrease in the power fluctuations, high power can be outputted from none of the amplifiers.

By contrast, in the power amplifier circuit 100 of the embodiment shown in FIG. 6, the amplifier circuit 106B is connected to the connection node N1C, which is a synthesis point, not only through the phase-shifting line 161C of the hybrid coupler CP3 but also through the phase-shifting line 153 having an electric length of one-eighth wavelength. The phase-shifting line 153 causes the load phase of the load impedance at the output end of the amplifier circuit 106B to be shifted by 90° compared to the comparative example in FIG. 5.

Then, for example, in a case where the phase φ=0° in the region where the antenna's load impedance R_{ANT} is greater than the characteristic impedance R_{L} (R_{L}<R_{ANT}), as the Smith chart in the lower right field in FIG. 6 shows, the peak amplifier 142A of the amplifier circuit 106A is located at a point PT11 rightward of the center CP on the Smith chart, and the carrier amplifier 141A of the amplifier circuit 106A is located at a point PT12 leftward of the center CP.

Meanwhile, the peak amplifier 142B of the amplifier circuit 106B is located at a point PT21 upward of the center CP, and the carrier amplifier 141B of the amplifier circuit 106B is located at a point PT22 downward of the center CP.

In this case, when the load phase φ fluctuates due to load fluctuations, the point indicating each amplifier rotates about the center CP on the Smith chart. Then, no matter how the load phase φ changes due to load fluctuations, at least one amplifier is located in a region leftward of the center CP on the Smith chart, i.e., a region where power higher than the average power is outputted.

As a result, in the power amplifier circuit 100 of the embodiment, as the graph in the upper right field of FIG. 6 shows, the phase difference of the load phase between the output power from each amplifier of the amplifier circuit 106A (lines LN11 and LN13) and the output power from each amplifier of the amplifier circuit 106B (lines LN12 and LN14) is 90°.

As a result, not only can power fluctuations due to load fluctuations be suppressed over the entire range of load phase, but also output power from either one of the amplifier circuits can be maintained to be higher than the average power at any load phase. Thus, robustness against load fluctuations can be further improved.

Note that the phase-shifting lines 151 and 152 provided at the input ends of the carrier amplifier 141B and the peak amplifier 142B, respectively, are provided to shift the phase which has been shifted by the phase-shifting line 153 by 45° further by 45°. The phase-shifting lines 151 and 152 can set the phase difference of the high-frequency signal supplied from the drive amplifier 130 to a multiple of 90°.

### (Amplifier Switching Operation)

In the first mode, each amplifier circuit in the power amplifier circuit 100 operates as a Doherty amplifier. Thus, switching the amplifiers to be used according to the power level of the input signal Pin makes it possible to improve the efficiency of the power amplifier circuit 100.

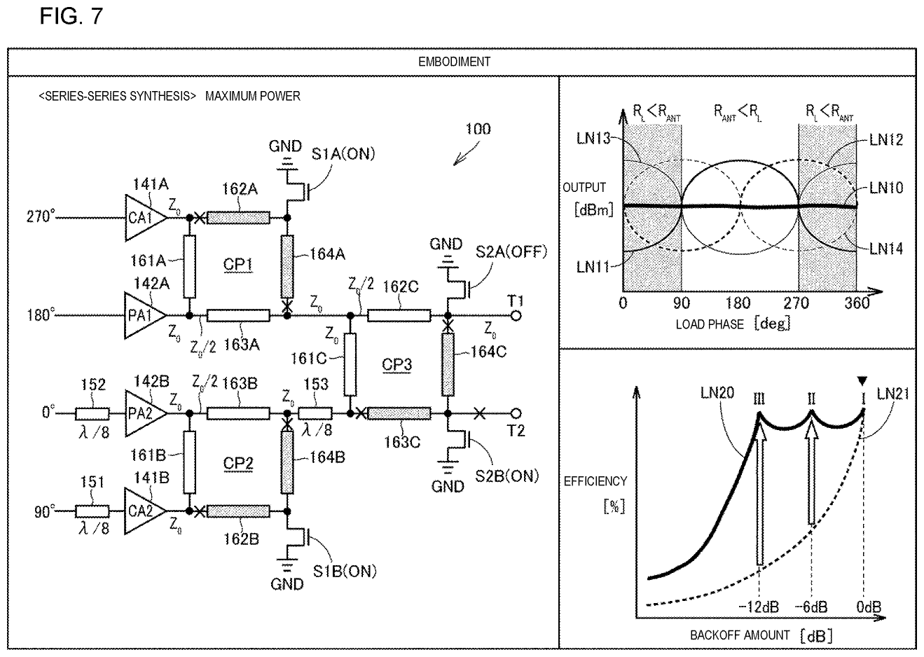

Using FIGS. 7 to 9, the following describes the relation between output power and efficiency on switching of the amplifiers in the amplifier circuits.

### (When Power is at Maximum)

FIG. 7 is a diagram illustrating an output from each amplifier when the power level of the input signal Pin is at maximum. The left field of FIG. 7 shows the operation status of each amplifier. Also, the circuit diagram in the left field depicts load impedance at each position when the load impedance of the antenna ANT1 is Z₀. Note that although not shown, in each hybrid coupler, the characteristic impedance of the phase-shifting lines 161A, 161B, and 161C and the phase-shifting lines 164A, 164B, and 164C is set to Z₀, and the characteristic impedance of the phase-shifting lines 162A, 162B, and 162C and the phase-shifting lines 163A, 163B, and 163C is set to Z₀/√2. The characteristic impedance of the phase-shifting line 153 is set to Z₀ as well.

In FIG. 7, the upper right field shows a graph of fluctuations of output power from the peak amplifier and the carrier amplifier in each amplifier circuit caused by load fluctuations, and the lower right field shows a graph indicating the relation between output power and efficiency on switching of the amplifiers.

In the graph shown in the lower right field, the horizontal axis represents output power backoff amount, and the vertical axis represents the efficiency of the power amplifier circuit 100. Note that solid line LN20 denotes the efficiency of the power amplifier circuit 100 of the embodiment, and broken line LN21 denotes the efficiency of a class AB amplifier capable of outputting the same maximum power as the power amplifier circuit 100, used alone. In the graph, (I) shows an operation mode for a case of maximum power, (II) shows an operation mode for a case where the power level is a second power value, and (III) shows an operation mode for a case where the power level is a third power value lower than the second power value.

Referring to FIG. 7, when the output power is at maximum, the peak amplifier and the carrier amplifier are both in operating state in both of the amplifier circuits 106A and 106B.

In this case, as with FIG. 6, in the amplifier circuit 106A, an output signal from the carrier amplifier 141A and an output signal from the peak amplifier 142A become in phase and are synthesized at the connection node N2A, and in the amplifier circuit 106B, an output signal from the carrier amplifier 141B and an output signal from the peak amplifier 142B become in phase and are synthesized at the connection node N2B. Further, an output signal from the amplifier circuit 106A and an output signal from the amplifier circuit 106B become in phase and are synthesized at the connection node N1C.

In this event, the phase-shifting line 153 shifts the load phase of the load impedance of each amplifier in the amplifier circuit 106B by 90° relative to that of each amplifier in the amplifier circuit 106A. As a result, as the graph in the upper right field shows, power fluctuations due to load fluctuations can be suppressed over the entire range of load phase, and also, at any load phase, output power from either one of the amplifier circuits can be maintained to be higher than the average power. Thus, robustness against load fluctuations can be further improved.

### (When Power Level Decreases)

Next, a description is given of how the power amplifier circuit 100 operates when the power level of the input signal Pin decreases from the maximum power. Because the amplifier circuits in the power amplifier circuit 100 are each a Doherty amplifier, the amplifiers are stopped as needed according to the power level of the input signal Pin to increase the load impedance, so that the overall efficiency of the power amplifier circuit 100 can be improved.

In the embodiment, the power amplifier circuit 100 is operated in the operation mode switched among three operation modes according to the power level of the input signal Pin. In each operation mode, the power supply voltage Vcc from the power supply circuit 40 is switched among three stages, namely VC1 to VC3 (VC1>VC2>VC3), according to the power level of the input signal Pin. In the above-described case where the power level of the input signal Pin is the maximum power (a first power value), the power supply voltage Vcc is set to VC1.

### (1) 6-dB Backoff

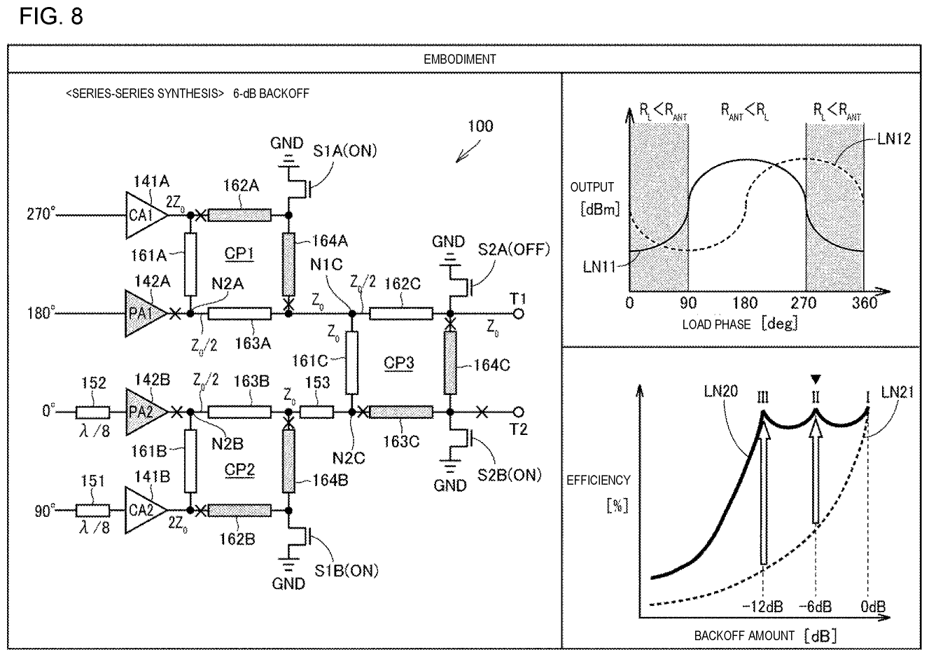

First, FIG. 8 is used to describe an operation mode employed when the power level of the input signal Pin is the second power value slightly smaller than the maximum power. In this case, the power supply voltage Vcc is set to VC2, and the operation mode corresponds to operation mode (II) in the graph in the lower right field.

In operation mode (II) in FIG. 8, in each amplifier circuit, the peak amplifier is in non-driving state, and only the carrier amplifier is in driving state. In this case, compared to a case with maximum power, the number of amplifiers used is reduced by half, and further, the load impedance of each carrier amplifier doubles (2Z₀). As a result, the efficiency of the carrier amplifier is enhanced, and thus, a backoff amount of 6 dB can be achieved, which makes it possible to improve the efficiency compared to a case where a class AB amplifier is used alone.

Note that because only the carrier amplifier is driven in each amplifier circuit in operation mode (II), power fluctuations due to load fluctuations cannot be cancelled out as the graph in the upper right field shows. Further, because the phase difference of the load phase between an output signal from the carrier amplifier 141A and an output signal from the peak amplifier 142A is 90°, power higher than the average power cannot be outputted when the load phase of the load impedance is in the range from 0° to 90°.

However, because the influence of a loss attributable to load fluctuations is notable when the power level is high, the influence of power fluctuations caused in a specific case where e.g., the load phase is from 0° to 90° is very small relative to the overall characteristics of the power amplifier circuit 100, compared to a case of the maximum power in operation mode (I). Thus, it is unlikely to be a substantial problem in terms of practical use.

### (2) 12-dB Backoff

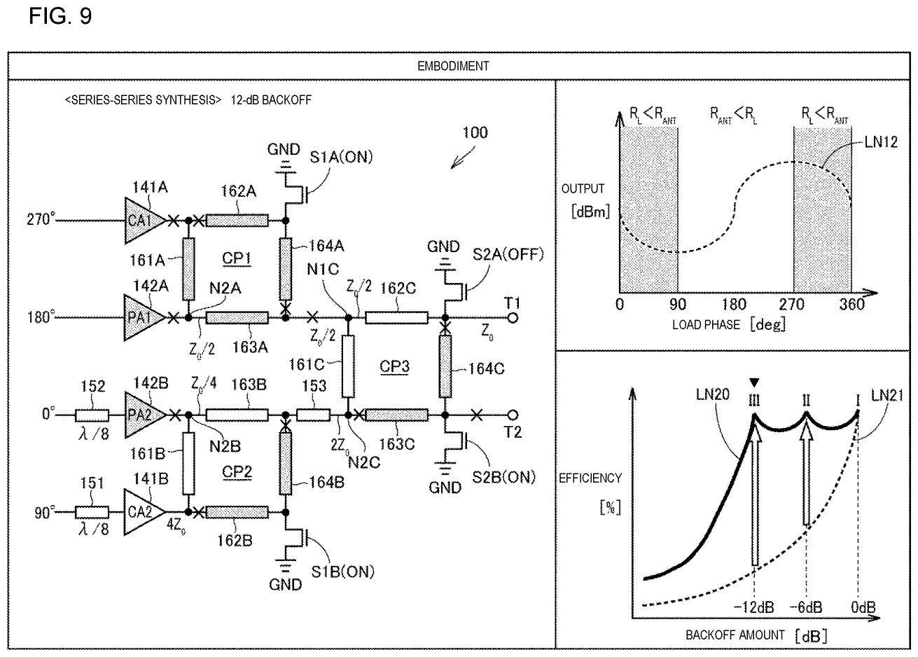

Next, FIG. 9 is used to describe operation mode (III) employed when the power level is the third power value, which is even smaller. The power supply voltage Vcc is set to VC3 in this case, and the operation mode corresponds to operation mode (III) in the graph in the lower right field.

In operation mode (III) in FIG. 9, in addition to the state in FIG. 8, the carrier amplifier 141A of the amplifier circuit 106A is also in non-driving state, and only the carrier amplifier 141B of the amplifier circuit 106B is in driving state.

In this event, because the carrier amplifier 141A is stopped, the number of amplifiers used is reduced by half. Further, the load impedance of the carrier amplifier 141B in operation further doubles compared to that in FIG. 8 and quadruples compared to that when the power level is at maximum. Because the efficiency of the carrier amplifier 141A is enhanced as a result of this, an additional 6-dB backoff is obtained, which means that a total of 12-dB backoff can be achieved.

Note that because only one amplifier is driven in the operation state in FIG. 9, power fluctuations caused by load fluctuations cannot be cancelled out. However, because this operation mode is employed with respect to an operation region where output power is very low, even if power fluctuations occur due to load fluctuations, they do not result in a significant loss. Thus, there is no problem in terms of practical use.

Note that the carrier amplifier 141A of the amplifier circuit 106A can instead be used as the amplifier used in operation mode (III). However, if the carrier amplifier 141A is used, in a case where a high-frequency signal is outputted to the antenna ANT1, the load impedance when the phase-shifting line 161C is seen from the connection node N1C does not become an open circuit, causing the phase-shifting line 161C and the phase-shifting line 153 to function as stubs in the signal passage path. Then, the stubs affect output signals more or less. For this reason, in a case of radiating radio waves from the antenna ANT1, the carrier amplifier 141B in operation mode (III) may be used.

Although radio waves are radiated from the antenna ANT1 in the above description of the first mode, a maximum of 12-dB backoff can be achieved by a similar amplifier switching operation in a case of radiating radio waves from the antenna ANT2 as well. However, in operation mode (III), not the carrier amplifier 141B of the amplifier circuit 106B, but the carrier amplifier 141A of the amplifier circuit 106A is brought to operating state.

As thus described, in the first mode, the antenna for radiating radio waves can be switched by switching of the switches S2A and S2B of the output circuit 107. In this event, the frequency band of the high-frequency signal is switched according to the antenna to be used, and thereby two different radio waves can be radiated using a common power amplifier circuit.

Further, two amplifier circuits operate as Doherty amplifiers, and output signals from them are synthesized after the output signal from one of the amplifier circuits passes through the phase-shifting line having an electric length of one-eighth wavelength. Thus, at the maximum power, fluctuations in output power due to load fluctuations can be suppressed over the entire range of phase, and also, the output power from either one of the amplifier circuits can be maintained to be higher than the average power. Thus, robustness against load fluctuations can be improved in the transmission circuit.

Also, a backoff amount of 12 dB can be achieved when the operation state of each amplifier functioning as a Doherty amplifier in the amplifier circuits is switched appropriately according to the power level of an output signal.

### (Second Mode)

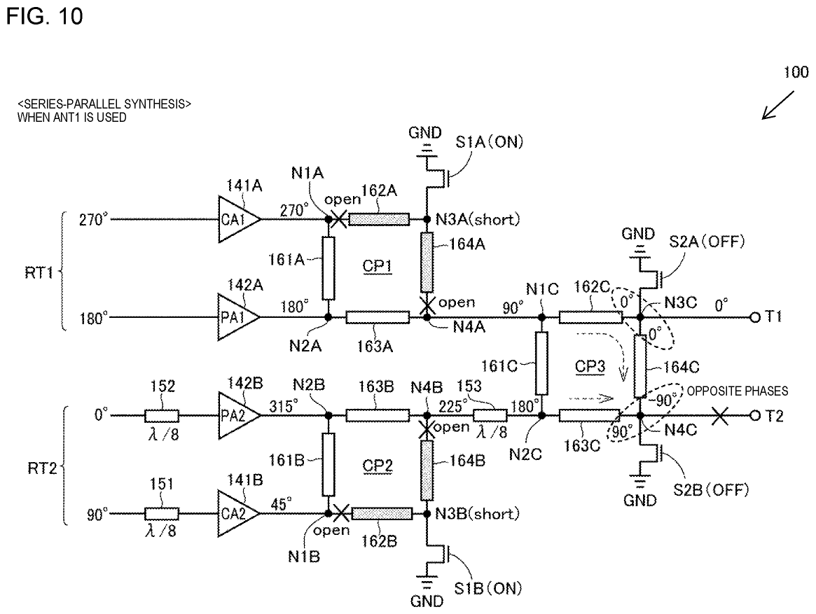

Next, a second mode is described using FIGS. 10 to 13. In the second mode, the switches S1A and S1B in the amplifier circuits 106A and 106B are both brought to a conducting state as in the first mode, and an output signal from the carrier amplifier and an output signal from the peak amplifier are series-synthesized. Thus, the amplifier circuits 106A and 106B function as Doherty amplifiers.

Meanwhile, in the output circuit 107, the switches S2A and S2B are both in a non-conducting state, and the connection nodes N3C and N4C are not grounded. In this case, in the hybrid coupler CP3, an output signal from the amplifier circuit 106A is conveyed from the connection node N1C to a route passing through the phase-shifting line 161C and a route passing through the phase-shifting line 162C. Similarly, an output signal from the amplifier circuit 106B is conveyed from the connection node N2C to a route passing through the phase-shifting line 161C and a route passing through the phase-shifting line 163C.

### (Antenna Switching Operation)

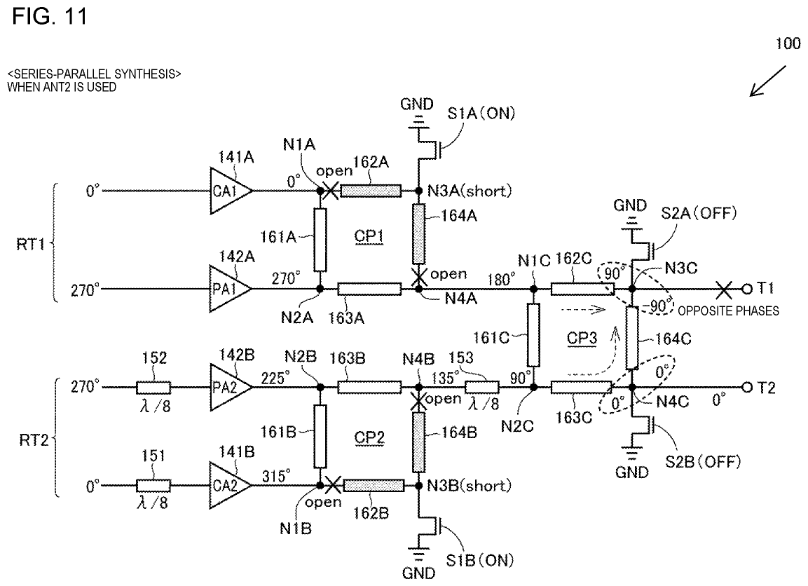

FIGS. 10 and 11 are diagrams illustrating antenna switching operation in the second mode. FIG. 10 shows a circuit state in a case where radio waves are radiated from the antenna ANT1, and FIG. 11 shows a circuit state in a case where radio waves are radiated from the antenna ANT2.

Referring to FIG. 10, when the phases of the high-frequency signals supplied to the amplifiers in the amplifier circuits are set as shown in FIG. 3 to the phases for radiating radio waves from the antenna ANT1, an output signal from the amplifier circuit 106A through the phase-shifting line 162C and an output signal from the amplifier circuit 106B through the phase-shifting lines 163C and 164C become in phase at the connection node N3C. Meanwhile, at the connection node N4C, an output signal from the amplifier circuit 106A through the phase-shifting lines 162C and 164C and an output signal from the amplifier circuit 106B through the phase-shifting line 163C have mutually opposite phases, and the two signals cancel out each other. As a result, high-frequency signals outputted from the amplifier circuits 106A and 106B are synthesized at the connection node N3C and outputted only from the output terminal T1.

This method where signals are synthesized with both of the output nodes of a hybrid coupler not grounded is referred to as “parallel synthesis” herein. Thus, the second mode is also referred to as “series-parallel synthesis mode”.

Next, referring to FIG. 11, in the second mode, when the phases of the high-frequency signals supplied to the amplifiers in the amplifier circuits are set as shown in FIG. 4 to the phases for radiating radio waves from the antenna ANT2, an output signal from the amplifier circuit 106A and an output signal from the amplifier circuit 106B have mutually opposite phases at the connection node N3C, and an output signal from the amplifier circuit 106A and an output signal from the amplifier circuit 106B become in phase at the connection node N4C. Thus, high-frequency signals outputted from the amplifier circuits 106A and 106B are synthesized at the connection node N4C and outputted only from the output terminal T2.

In this way, in the second mode, the antenna for radiating radio waves can be switched by the drive amplifier 130 switching the phases of the signals supplied to the amplifiers in the amplifier circuits 106A and 106B, without the switches S2A and S2B in the output circuit 107 being switched.

### (Amplifier Switching Operation)

In the second mode as well, the amplifier circuits in the power amplifier circuit 100 operate as Doherty amplifiers. Thus, switching the amplifiers to use according to the power level of the input signal Pin makes it possible to improve the efficiency of the power amplifier circuit 100.

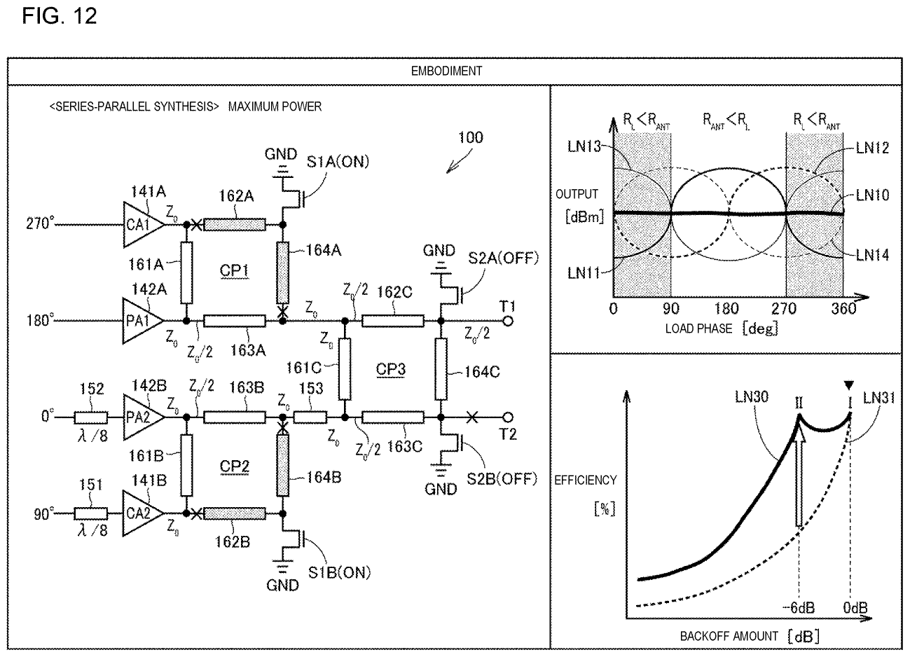

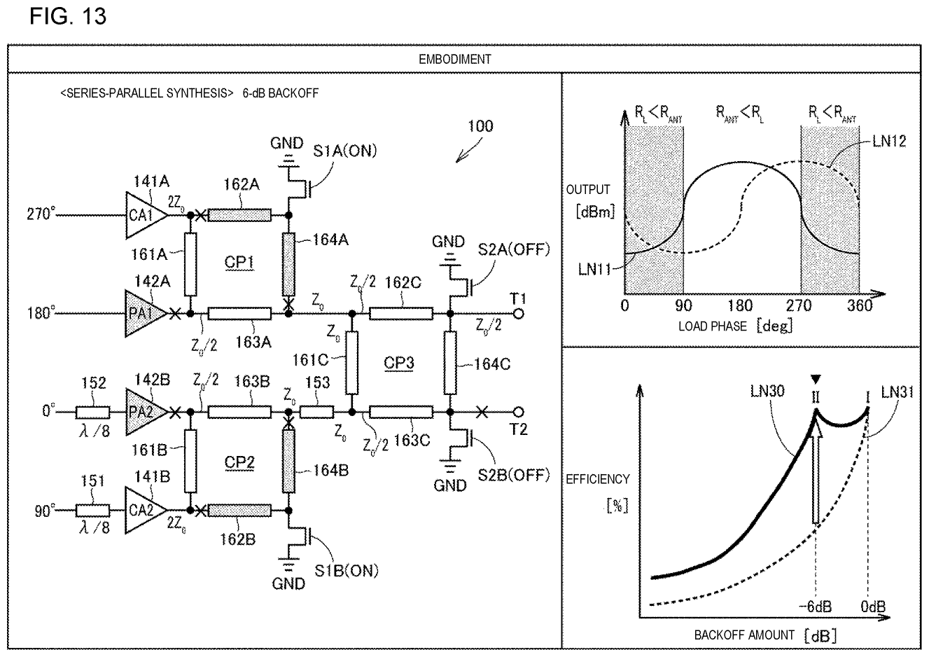

Using FIGS. 12 and 13, the following describes the relation between output power and efficiency on switching of the amplifiers in the amplifier circuits. In the second mode, Doherty amplifiers are formed in the amplifier circuits, but a Doherty amplifier is not formed by the amplifier circuits 106A and 106B and the phase-shifting line 161C of the output circuit 107. For this reason, as the graphs in the lower right fields of FIGS. 12 and 13 show, there are two operation modes: operation mode (I) and operation mode (II). In the graphs in the lower right fields of FIGS. 12 and 13, line LN30 denotes the efficiency of the power amplifier circuit 100 of the embodiment, and broken line LN31 denotes the efficiency of a class AB amplifier capable of outputting the same maximum power as the power amplifier circuit 100, used alone.

Note that FIGS. 12 and 13 illustrate an example where radio waves are radiated from the antenna ANT1.

### (When Power is at Maximum)

FIG. 12 is a diagram illustrating outputs from the amplifiers in operation mode (I) employed when the power level of the input signal Pin is maximum power. When the power is at maximum, the switches S2A and S2B in the hybrid coupler CP3 are in different states, but as with the first mode, a synthesized signal of an output signal from the carrier amplifier and an output signal from the peak amplifier in each amplifier circuit is synthesized in the hybrid coupler CP3 and outputted from the output terminal T1.

In this event, the load phase of the load impedance of each amplifier in the amplifier circuit 106B is shifted by 90° relative to that of each amplifier in the amplifier circuit 106A. As a result, as shown in the graph in the upper right field of FIG. 12, not only can power fluctuations due to load fluctuations be suppressed over the entire range of load phase, but also output power from either one of the amplifier circuits can be maintained to be higher than the average power at any load phase. Thus, robustness against load fluctuations can be further improved.

### (6-dB Backoff)

Next, a description is given of operation mode (II) employed when the power level of the input signal Pin is the second power value lower than the maximum power.

In operation mode (II) in the second mode, in each amplifier circuit, the peak amplifier is in non-driving state, and only the carrier amplifier is in driving state. In this case, compared to the case with the maximum power, the number of amplifiers used is reduced by half, and the load impedance of each carrier amplifier doubles (2Z₀). As a result, the efficiency of the carrier amplifier is enhanced, and thus, a backoff amount of 6 dB can be achieved, which makes it possible to improve the efficiency compared to a case where a class AB amplifier is used alone.

Note that in the second mode, like in the first mode, the peak amplifier in each amplifier circuit is stopped in operation mode (II), and thus, power fluctuations due to load fluctuations cannot be cancelled out. Also, because the phase difference of the load phase between an output signal from the carrier amplifier 141A and an output signal from the peak amplifier 142A is 90°, power higher than the average power cannot be outputted when the load phase of the load impedance is in the range from 0° to 90°.

As thus described, in the second mode as well, the antenna for radiating radio waves can be switched by the drive amplifier 130 switching the high-frequency signals supplied to the amplifiers in the amplifier circuits. Then, by switching of the antenna and switching of the frequency band of the high-frequency signal supplied, two different radio waves can be radiated using a common power amplifier circuit.

Further, synthesizing output signals from two amplifier circuits using a phase-shifting line having an electric length of one-eighth wavelength makes it possible to improve robustness against load fluctuations when the power is at maximum. Also, a backoff amount of 6 dB can be achieved when the operation state of each amplifier functioning as a Doherty amplifier in the amplifier circuits is switched appropriately according to the power level of an output signal.

### (Third Mode)

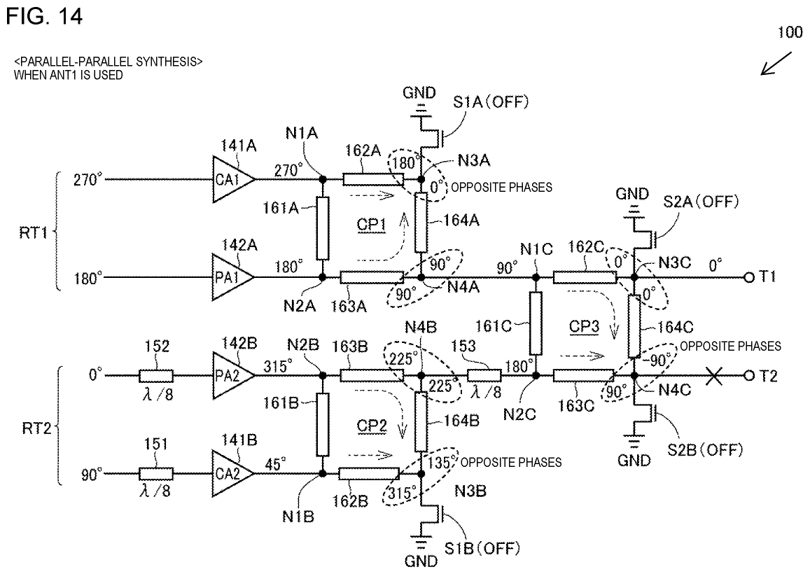

Next, a third mode is described using FIGS. 14 to 16. In the third mode, the switches S1A and S1B in the amplifier circuits and the switches S2A and S2B in the output circuit 107 are all set to a non-conducting state. As a result, in the hybrid couplers CP1 to CP3, signals received at two input nodes are parallel-synthesized. Thus, the third mode is also referred to as “parallel-parallel synthesis mode”.

### (Antenna Switching Operation)

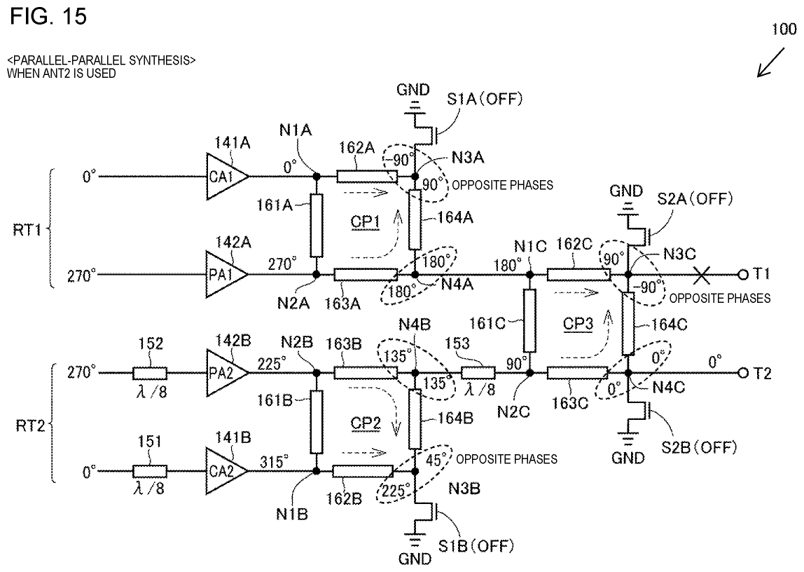

FIGS. 14 and 15 are diagrams illustrating antenna switching operation in the third mode. FIG. 14 shows a circuit state in a case where radio waves are radiated from the antenna ANT1, and FIG. 15 shows a circuit state in a case where radio waves are radiated from the antenna ANT2.

Referring to FIG. 14, in the third mode, in the amplifier circuit 106A, an output signal from the carrier amplifier 141A and an output signal from the peak amplifier 142A have mutually opposite phases at the connection node N3A, and an output signal from the carrier amplifier 141A and an output signal from the peak amplifier 142A become in phase at the connection node N4A. Thus, the output signal from the carrier amplifier 141A and the output signal from the peak amplifier 142A are synthesized at the connection node N4A.

Similarly, in the amplifier circuit 106B, an output signal from the carrier amplifier 141B and an output signal from the peak amplifier 142B are synthesized at the connection node N4B.

When the phases of the high-frequency signals supplied to the amplifiers in the amplifier circuits are set to the phases for radiating radio waves from the antenna ANT1, the output signal from the amplifier circuit 106B at the connection node N2C of the hybrid coupler CP3 has a 90° phase advance relative to the output signal from the amplifier circuit 106A at the connection node N1C.

Thus, in the hybrid coupler CP3, an output signal from the amplifier circuit 106A and an output signal from the amplifier circuit 106B become in phase at the connection node N3C and have mutually opposite phases at the connection node N4C. As a result, high-frequency signals outputted from the amplifier circuits 106A and 106B are synthesized at the connection node N3C and outputted only from the output terminal T1.

Next, referring to FIG. 15, in the third mode, when the phases of the high-frequency signals supplied to the amplifiers in the amplifier circuits are set to the phases for radiating radio waves from the antenna ANT2, an output signal from the amplifier circuit 106A and an output signal from the amplifier circuit 106B have mutually opposite phases at the connection node N3C and become in phase at the connection node N4C. As a result, high-frequency signals outputted from the amplifier circuits 106A and 106B are synthesized at the connection node N4C and outputted only from the output terminal T2.

In this way, in the third mode as well, the antenna for radiating radio waves can be switched by the drive amplifier 130 switching the phases of the signals supplied to the amplifiers in the amplifier circuits 106A and 106B, without the switches S2A and S2B in the output circuit 107 being switched.

In the third mode, signals are parallel-synthesized in each hybrid coupler, and a Doherty amplifier is not formed by the amplifier circuits 106A and 106B and the output circuit 107. Thus, in the third mode, efficiency cannot be improved by switching of the amplifiers according to the power level of the input signal Pin. In other words, the operation mode cannot be switched to the first or second mode, and only the operation mode where all the amplifiers are in operating state can be used.

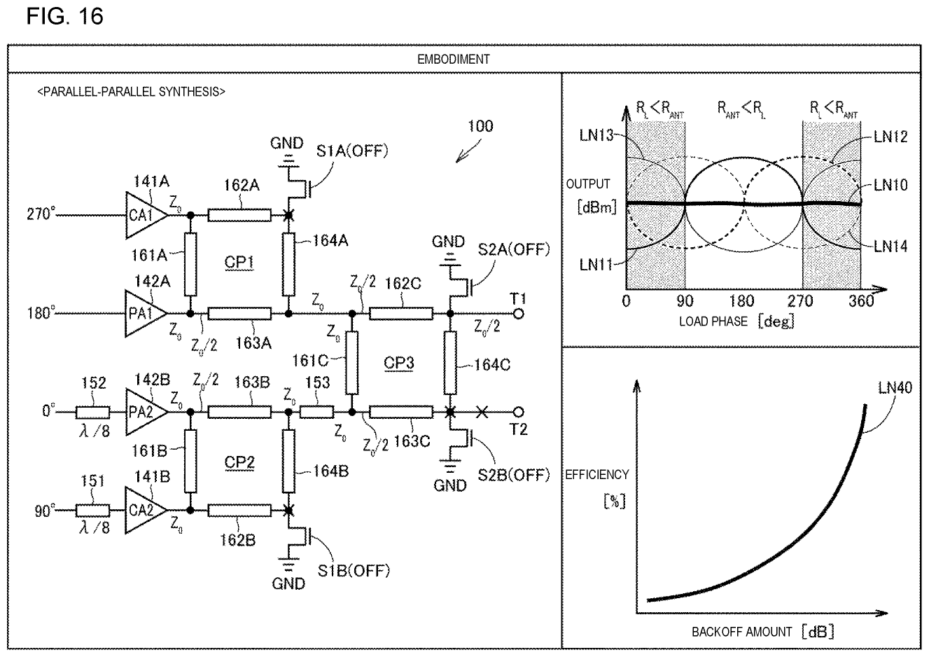

FIG. 16 is a diagram illustrating outputs from the amplifiers in the third mode. Note that FIG. 16 illustrates an example where radio waves are radiated from the antenna ANT1.

As described with FIGS. 14 and 15, in the third mode, there is only one operation mode: the amplifiers in the amplifier circuits 106A and 106B are in operating state at all times. Thus, as line LN40 in the lower right field of FIG. 16 shows, efficiency in relation to the output power is similar to that of a case where a class AB amplifier is used alone.

In each amplifier circuit, fluctuations in the load impedance of the carrier amplifier and fluctuations in the load phase of the load impedance of the peak amplifier have mutually opposite phases, and therefore, power fluctuations due to load fluctuations can be suppressed over the entire range of phase.

Also, the phase-shifting line 153 shifts the load phase of the load impedance of each amplifier in the amplifier circuit 106B by 90° relative to that of each amplifier in the amplifier circuit 106A. As a result, robustness against load fluctuations can be further improved.

As thus described, in each of the operation modes of the first to third modes, in a transmission circuit in which two amplifier circuits are synthesized by a hybrid coupler, one of the amplifier circuits is connected to the hybrid coupler through a phase-shifting line having an electric length of one-eighth wavelength, which makes it possible to improve robustness against antenna load fluctuations.

The “antennas ANT1 and ANT2” in the embodiment respectively correspond to the “first antenna” and the “second antenna” in the present disclosure. The “output terminals T1 and T2” in the embodiment respectively correspond to the “first output terminal” and the “second output terminal” in the present disclosure. The “amplifier circuits 106A and 106B” in the embodiment respectively correspond to the “first amplifier circuit” and the “second amplifier circuit” in the present disclosure. The “phase-shifting lines 151, 152, and 153” in the embodiment respectively correspond to the “first phase-shifting line,” the “second phase-shifting line,” and the “third phase-shifting line” in the present disclosure. The “carrier amplifiers 141A and 141B” in the embodiment respectively correspond to the “first carrier amplifier” and the “second carrier amplifier” in the present disclosure. The “peak amplifiers 142A and 142B” in the embodiment respectively correspond to the “first peak amplifier” and the “second peak amplifier” in the present disclosure. The “switches S1A, S1B, S2A, and S2B” in the embodiment respectively correspond to the “first switch,” the “second switch,” the “third switch,” and the “fourth switch” in the present disclosure.

The “hybrid couplers CP1, CP2, and CP3” in the embodiment respectively correspond to the “first hybrid coupler,” the “second hybrid coupler,” and the “third hybrid coupler” in the present disclosure. The “connection nodes N1A, N1B, and N1C” in the embodiment each correspond to the “first input node” in the present disclosure. The “connection nodes N2A, N2B, and N2C” in the embodiment each correspond to the “second input node” in the present disclosure. The “connection nodes N3A, N3B, and N3C” in the embodiment each correspond to the “first output node” in the present disclosure. The “connection nodes N4A, N4B, and N4C” in the embodiment each correspond to the “second output node” in the present disclosure.

The “phase-shifting lines 161A, 161B, and 161C” in the embodiment each correspond to the “first line” in the present disclosure. The “phase-shifting lines 162A, 162B, and 162C” in the embodiment each correspond to the “second line” in the present disclosure. The “phase-shifting lines 163A, 163B, and 163C” in the embodiment each correspond to the “third line” in the present disclosure. The “phase-shifting lines 164A, 164B, and 164C” in the embodiment each correspond to the “fourth line” in the present disclosure.

The embodiment disclosed herein is exemplary in all aspects and should not be construed as limiting. The scope of the present disclosure is defined not by the description of the embodiment given above but by the scope of claims and is intended to include all modifications within the meaning and scope equivalent to the scope of claims.

What is claimed is:

1. A transmission circuit configured to amplify and transmit a high-frequency signal to a first antenna and a second antenna respectively corresponding to a first frequency band and a second frequency band that are different from each other, the transmission circuit comprising:
an input terminal configured to receive a high-frequency signal;
a first output terminal configured to connect to the first antenna;
a second output terminal configured to connect to the second antenna;
a first amplifier circuit and a second amplifier circuit configured to amplify the high-frequency signal received by the input terminal;
an output circuit connected to the first amplifier circuit, the second amplifier circuit, the first output terminal, and the second output terminal; and
a first phase-shifting line, a second phase-shifting line, and a third phase-shifting line each having an electric length equal to one-eighth wavelength of a signal passed by the transmission circuit,
wherein the first amplifier circuit comprises a first carrier amplifier, a first peak amplifier, a first hybrid coupler, and a first switch,
wherein the second amplifier circuit comprises a second carrier amplifier, a second peak amplifier, a second hybrid coupler, and a second switch,
wherein the output circuit comprises a third hybrid coupler, a third switch, and a fourth switch,
wherein the first hybrid coupler, the second hybrid coupler, and the third hybrid coupler each have a first input node, a second input node, a first output node, and a second output node,
wherein the first phase-shifting line is connected to an input of the second carrier amplifier,
wherein the second phase-shifting line is connected to an input of the second peak amplifier,
wherein the first input node of the first hybrid coupler is connected to an output of the first carrier amplifier,
wherein the second input node of the first hybrid coupler is connected to an output of the first peak amplifier,
wherein the first output node of the first hybrid coupler is connected to a ground potential through the first switch,
wherein the first input node of the second hybrid coupler is connected to an output of the second carrier amplifier,
wherein the second input node of the second hybrid coupler is connected to an output of the second peak amplifier,
wherein the first output node of the second hybrid coupler is connected to the ground potential through the second switch,
wherein the first input node of the third hybrid coupler is connected to the second output node of the first hybrid coupler,
wherein the second input node of the third hybrid coupler is connected to the second output node of the second hybrid coupler through the third phase-shifting line,
wherein the first output node of the third hybrid coupler is connected to the first output terminal and is also connected to the ground potential through the third switch, and
wherein the second output node of the third hybrid coupler is connected to the second output terminal and is also connected to the ground potential through the third switch.

2. The transmission circuit according to claim 1,
wherein the transmission circuit has a first mode, a second mode, and a third mode as operation modes, and
wherein the operation modes are switched by switching of the first to fourth switches.

3. The transmission circuit according to claim 2,
wherein the first hybrid coupler, the second hybrid coupler, and the third hybrid coupler each comprise a first line, a second line, a third line, and a fourth line connected annularly, and
wherein in each hybrid coupler:
the first line is connected between the first input node and the second input node,
the second line is connected between the first input node and the first output node,
the third line is connected between the second input node and the second output node, and
the fourth line is connected between the first output node and the second output node.

4. The transmission circuit according to claim 3, wherein in the first mode:
the first switch and the second switch are in a conducting state,
in outputting the high-frequency signal from the first output terminal, the third switch is in a non-conducting state, and the fourth switch is in a conducting state, and
in outputting the high-frequency signal from the second output terminal, the third switch is in a conducting state, and the fourth switch is in a non-conducting state.

5. The transmission circuit according to claim 4,
wherein in the first amplifier circuit, a Doherty amplifier is formed by the first carrier amplifier, the first peak amplifier, and the first line of the first hybrid coupler,
wherein in the second amplifier circuit, a Doherty amplifier is formed by the second carrier amplifier, the second peak amplifier, and the first line of the second hybrid coupler, and
wherein in each amplifier circuit, a phase of a signal supplied to the carrier amplifier is 90° ahead of a phase of a high-frequency signal supplied to the peak amplifier.

6. The transmission circuit according to claim 5, wherein in a case where a power level of a high-frequency signal to be outputted is a first power value, the first carrier amplifier, the first peak amplifier, the second carrier amplifier, and the second peak amplifier are in a driving state.

7. The transmission circuit according to claim 6, wherein in a case where the power level of the high-frequency signal to be outputted is a second power value smaller than the first power value:
the first carrier amplifier and the second carrier amplifier are in the driving state, and
the first peak amplifier and the second peak amplifier are in a non-driving state.

8. The transmission circuit according to claim 7, wherein in a case where the power level of the high-frequency signal to be outputted is a third power value smaller than the second power value:
in outputting the high-frequency signal from the first output terminal, the second carrier amplifier is in the driving state, and the first carrier amplifier, the first peak amplifier, and the second peak amplifier are in a non-driving state, and
in outputting the high-frequency signal from the second output terminal, the first carrier amplifier is in the driving state, and the second carrier amplifier, the first peak amplifier, and the second peak amplifier is in a non-driving state.

9. The transmission circuit according to claim 3, wherein in the second mode, the first switch and the second switch are in a conducting state, and the third switch and the fourth switch are in a non-conducting state.

10. The transmission circuit according to claim 9,
wherein in the first amplifier circuit, a Doherty amplifier is formed by the first carrier amplifier, the first peak amplifier, and the first line of the first hybrid coupler,
in the second amplifier circuit, a Doherty amplifier is formed by the second carrier amplifier, the second peak amplifier, and the first line of the second hybrid coupler, and
in each amplifier circuit, a phase of a signal supplied to the carrier amplifier is 90° ahead of a phase of a high-frequency signal supplied to the peak amplifier.

11. The transmission circuit according to claim 10, wherein in a case where a power level of a high-frequency signal to be outputted is a first power value, the first carrier amplifier, the first peak amplifier, the second carrier amplifier, and the second peak amplifier are in a driving state.

12. The transmission circuit according to claim 11, wherein in a case where the power level of the high-frequency signal to be outputted is a second power value smaller than the first power value:
the first carrier amplifier and the second carrier amplifier are in the driving state, and
the first peak amplifier and the second peak amplifier are in a non-driving state.

13. The transmission circuit according to claim 3, wherein in the third mode, the first to fourth switches are in a non-conducting state.

14. The transmission circuit according to claim 1, further comprising:
a phase adjuster circuit configured to branch the high-frequency signal received by the input terminal into high-frequency signals, adjust phases of the branched high-frequency signals, and convey the high-frequency signals to the first amplifier circuit and the second amplifier circuit,
wherein the phase adjuster circuit is configured to switch the phase of the high-frequency signal conveyed to each carrier amplifier and each peak amplifier according to a frequency band of the high-frequency signal to be transmitted.

15. The transmission circuit according to claim 14,
wherein in outputting the high-frequency signal from the first output terminal, the phase adjuster circuit is configured to supply the first peak amplifier with a signal that is delayed 90° relative to a signal supplied to the first carrier amplifier, to supply the second peak amplifier with a signal that is 90° advanced relative to the signal supplied to the first carrier amplifier, and to supply the second carrier amplifier with a signal that is 180° advanced relative to the signal supplied to the first carrier amplifier, and
wherein in outputting the high-frequency signal from the second output terminal, the phase adjuster circuit is configured to supply the first peak amplifier and the second peak amplifier with a signal that is delayed 90° relative to the signal supplied to the first carrier amplifier, and to supply the second carrier amplifier with a signal in the same phase as the signal supplied to the first carrier amplifier.

16. The transmission circuit according to claim 14, further comprising:
a control circuit configured to control the first to fourth switches and the phase adjuster circuit.

17. A communication device comprising:
the transmission circuit according to claim 1;
a signal processing circuit configured to process the high-frequency signal supplied to the transmission circuit; and
the first antenna and the second antenna configured to radiate the high-frequency signal amplified by the transmission circuit as a radio wave.
